(19) United States
(12) Patent Application Publication
(10) Pub. No.: US 2016/0119714 A1
(43) Pub. Date: Apr. 28, 2016

(54) AUDIO POWER LIMITING BASED ON THERMAL MODELING

(71) Applicant: Texas Instruments Incorporated, Dallas, TX (US)

(72) Inventors: Kim N. Madsen, Skovlunde (DK); Theis H. Christiansen, Solrod (DK); Søren B. Poulsen, Malov (DK)

(73) Assignee: Texas Instruments Incorporated, Dallas, TX (US)

(21) Appl. No.: 14/870,038

(22) Filed: Sep. 30, 2015

Related U.S. Application Data
(60) Provisional application No. 62/060,359, filed on Oct. 6, 2014.

(51) Int. Cl. H04R 3/00; H03G 3/30

(52) U.S. Cl. CPC H04R 3/007; H03G 3/30

(57) ABSTRACT

Systems and methods for audio power limiting based on thermal modeling are described. In some embodiments, a method includes monitoring a first temperature of a power die within an audio system; monitoring a second temperature of a digital die within the audio system; and using the first and second temperatures to limit an amplitude of an audio signal provided to a Metal-Oxide-Semiconductor Field-Effect Transistor (MOSFET) of an amplifier within the audio system to keep an operating temperature of the MOSFET under a thermal protection threshold without stopping the audio signal from being output by the audio system.

### CROSS-REFERENCE TO RELATED APPLICATIONS

This application claims priority to U.S. Provisional Patent Application Ser. No. 62/060,359 titled “POWER MOSFET THERMAL MODEL ESTIMATOR” and filed on Oct. 6, 2014, which is incorporated by reference herein.

### TECHNICAL FIELD

This specification is directed, in general, to electronic circuits, and, more specifically, to systems and methods for audio power limiting based on thermal modeling.

### BACKGROUND

A switching or class-D amplifier is an electronic circuit in which power transistors operate as switches rather than linear devices—as is the case with analog amplifiers. An advantage of class-D amplifiers over analog amplifiers is that their switching mechanisms are more efficient it terms of energy, with less power being dissipated as heat. Nonetheless, even when using class-D amplifiers, over-temperature conditions still occur.

A conventional approach to dealing with over-temperature conditions includes the use of “latched protection.” When implementing “latched protection,” a switching amplifier monitors its power transistor's temperature, and, if a temperature threshold is met, the amplifier turns off the power stage altogether. In some systems, “latched protection” may be further enhanced by including a thermal warning at a lower threshold.

The inventors have recognized, however, that “latched protection” invariably leads to disruption of playback for the time it takes the audio system to cool down, which can be highly annoying to the end-user. To avoid this problem, audio system designers will generally not allow an amplifier to get close to its shutdown temperature by over-designing the size of its power transistors and heat sinks.

### SUMMARY

Systems and methods for audio power limiting based on thermal modeling are described. In an illustrative, non-limiting embodiment, a method may comprise monitoring a first temperature of a power die within an audio system; monitoring a second temperature of a digital die within the audio system; and using the first and second temperatures to limit an amplitude of an audio signal provided to a Metal-Oxide-Semiconductor Field-Effect Transistor (MOSFET) of an amplifier within the audio system to keep an operating temperature of the MOSFET under a thermal protection threshold without stopping the audio signal from being output by the audio system.

In various implementations, using the first and second temperatures includes using a thermal model. The thermal model includes a 2nd order state space model. The model uses a plurality of parameters including a maximum temperature for the power die and a maximum temperature for the digital die, a thermal time constant for the MOSFET and a thermal time constant for the digital die, a thermal resistance for the MOSFET and a thermal resistance for the digital die, and/or a thermal resistance between the MOSFET and an ambient where the MOSFET is located. The monitoring operations may be performed continuously or periodically, and wherein the amplitude of the audio signal is limited according to latest monitored first and second temperatures.

In another illustrative, non-limiting embodiment, an audio system may comprise an analog circuit comprising a power amplifier and a MOSFET within the power amplifier; and a digital circuit coupled to the analog circuit, the digital circuit comprising: an audio signal source; a digital-to-analog converter (DAC) coupled to the audio signal source and to the power amplifier; and a controller coupled to the audio signal source, the controller configured to: periodically receive a first temperature of the digital circuit; periodically receive a second temperature of the MOSFET, wherein the first and second temperatures change over time; and use the first and second temperatures to dynamically limit an amplitude of an audio signal provided by the audio signal source to the DAC in order to keep an operating temperature of the MOSFET under a thermal protection threshold without stopping the audio signal from being output by the analog circuit.

The controller may be further configured to estimate a plurality of thermal parameters, at least in part, by replacing the audio signal with a test signal prior to performing the limiting operation. In some cases, the controller may comprise a power integrator coupled to the thermal model estimator. Additionally or alternatively, the controller may include a power limiter coupled to the power integrator and to the audio signal source.

In yet another illustrative, non-limiting embodiment, a circuit may comprise a controller; and a memory coupled to the controller, the memory having program instructions stored thereon that, upon execution by the controller, cause the circuit to: monitor a first temperature of an analog die; monitor a second temperature of a digital die; and use the first and second temperatures to limit an amplitude of an audio signal provided to a MOSFET to keep an operating temperature of the MOSFET under a thermal protection threshold without stopping an audio signal from being output by the MOSFET.

### BRIEF DESCRIPTION OF THE DRAWINGS

Having thus described the invention(s) in general terms, reference will now be made to the accompanying drawings, wherein:

FIG. 1 is a diagram of examples of devices where certain systems and methods described herein may be implemented according to some embodiments.

FIG. 2 is a block diagram of an example of an audio system according to some embodiments.

FIG. 3 is a block diagram of an example of a circuit for audio power limiting based on thermal modeling according to some embodiments.

FIG. 4 is a block diagram of the circuit being used in a parameter estimation mode according to some embodiments.

FIG. 5 is a flowchart of an example of a method for audio power limiting based on thermal modeling according to some embodiments.

FIG. 6 is a graph of various temperature and power measurements performed by the circuit according to some embodiments.

### DETAILED DESCRIPTION

The invention(s) now will be described more fully hereinafter with reference to the accompanying drawings. The invention(s) may, however, be embodied in many different forms and should not be construed as limited to the embodiments set forth herein. Rather, these embodiments are provided so that this disclosure will be thorough and complete, and will fully convey the scope of the invention(s) to a person of ordinary skill in the art. A person of ordinary skill in the art may be able to use the various embodiments of the invention(s).

Embodiments disclosed herein are directed to systems and methods for performing audio power limiting based on thermal modeling. A thermal model of a MOSFET is implemented in a controller, based upon parameters estimated using a feedback control loop of both the power die (close to the MOSFET temperature) and the digital die (close to power pad temperature). The model may then be used to limit the output power before the thermal protection threshold is reached. As a result, that output signal can always be made present, albeit with a reduced level, thus effecting a thermal fold back.

The fold back level is based on the actual used device and Printed Circuit Board (PCB) layout performance. Parameter estimation can be performed in the actual user end equipment, and these continuously monitored model parameters may be modified on the fly. Again, because the thermal model and the model parameter estimations may be performed on the customer's actual PCB implementation; therefore each system can be operated with higher power outputs—each individual system may always output the maximum power that it can safely sustain.

In many implementations, some of the systems and methods disclosed herein may be incorporated into a wide range of audio-enabled electronic devices including, for example, computer systems, portable audio systems, consumer electronics, automotive systems, and professional audio equipment.

Examples of consumer electronics include television sets, A/V receivers, home theater or sound systems, set-top boxes, docking stations, soundbars, sound projectors, etc. Examples of portable audio systems include tablets, smartphones, media players, camcorders, etc. Examples of automotive audio systems include audio distribution, infotainment, in-seat entertainment, etc. Examples of professional audio systems include recording, live and installation sound, musical instruments, etc. It should be noted, however, that these examples are not limiting, but only demonstrative of the various types of systems which may incorporate the present embodiments, and that additional applications may be possible. More generally, these systems and methods may be incorporated into any device or system having one or more electronic audio parts or components.

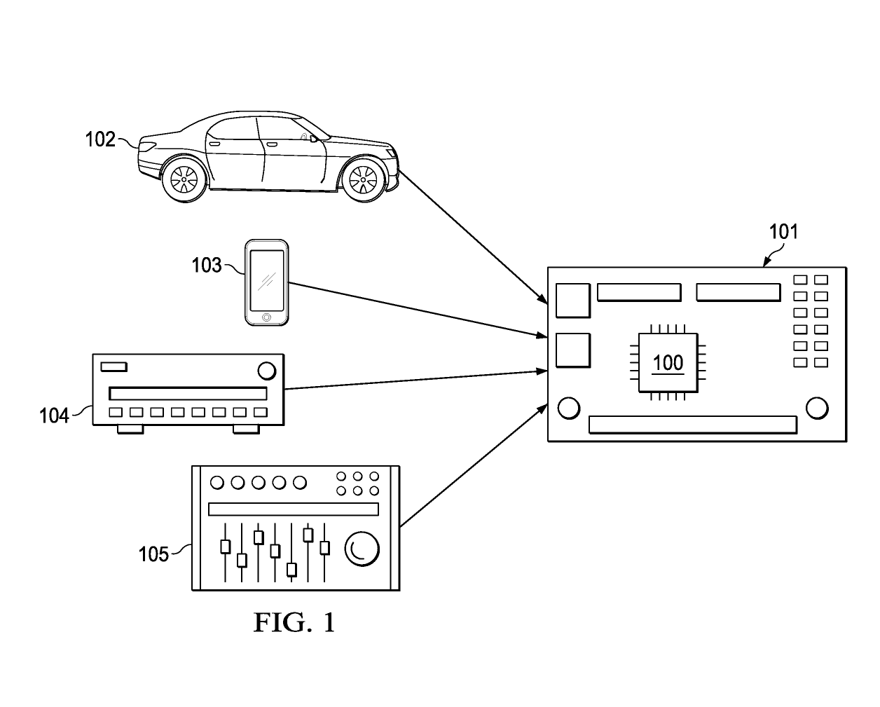

Turning to FIG. 1, a diagram of an environment where certain systems and methods described herein may be implemented is depicted. As illustrated, one or more devices or systems such as, for example, automobile 102, smartphone 103, A/V receiver 104, and/or audio recording equipment 105 (or any other audio-enabled device or system) may include printed circuit board (PCB) 101 having chip 100 mounted thereon. In some embodiments, chip 100 may include one or more analog, digital, and/or mixed signal integrated circuits (ICs) configured to perform audio power limiting based on thermal modeling, as discussed in more detail below.

In one embodiment, chip 100 may include an electronic component package configured to be mounted onto PCB 101 using a suitable packaging technology such as Ball Grid Array (BGA) packaging, pin mount packaging, or the like. In some applications, PCB 101 may be mechanically mounted within or fastened onto the electronic device. In other implementations, however, PCB 101 may take a variety of forms and/or may include a plurality of other elements or components in addition to chip 100. Moreover, in some embodiments, PCB 101 may not be used, and chip 100 may be integrated with other components of the electronic device without PCB 101.

Examples of IC(s) include a System-On-Chip (SoC), an Application Specific Integrated Circuit (ASIC), a Digital Signal Processor (DSP), a Field-Programmable Gate Array (FPGA), a processor, a microprocessor, a controller, a Microcontroller Unit (MCU), or the like. Additionally, IC(s) may include a memory circuit or device such as a Random Access Memory (RAM) device, a Static RAM (SRAM) device, a Magnetoresistive RAM (MRAM) device, a Nonvolatile RAM (NVRAM), and/or a Dynamic RAM (DRAM) device such as Synchronous DRAM (SDRAM), a Double Data Rate (DDR) RAM, an Erasable Programmable Read Only Memory (EPROM), an Electrically Erasable Programmable ROM (EEPROM), etc. IC(s) may also include one or more mixed-signal or analog circuits, such as, for example, Analog-to-Digital Converter (ADCs), Digital-to-Analog Converter (DACs), Phased Locked Loop (PLLs), oscillators, filters, amplifiers, etc.

As such, an IC within chip 100 may include a number of different portions, areas, or regions. These various portions may include one or more processing cores, cache memories, internal bus(es), timing units, controllers, analog sections, mechanical elements, etc. Thus, in various embodiments, IC(s) may include a circuit configured to receive one or more supply voltages (e.g., two, three, four, etc.).

Although the example of FIG. 1 shows electronic chip 100 in monolithic form, it should be understood that, in alternative embodiments, various systems and methods described herein may be implemented with discrete components. For example, in some cases, one or more discrete capacitors, inductors, transformers, transistors, registers, logic gates, etc. may be physically located outside of chip 100 (e.g., elsewhere on PCB 101).

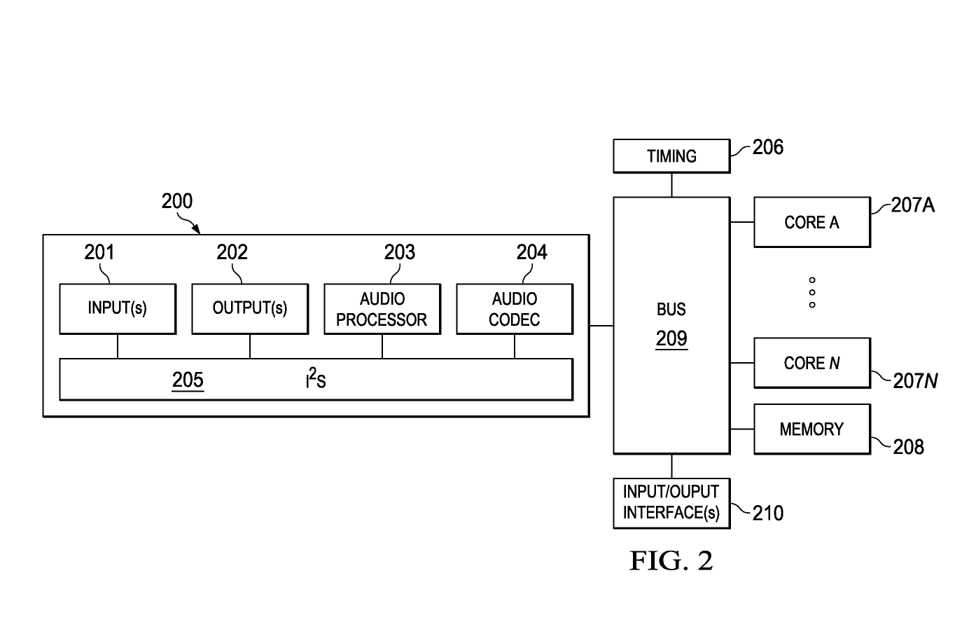

FIG. 2 is a block diagram of an example of IC 200 within chip 100. In some embodiments, IC 200 may include an electronic circuit configured to perform audio power limiting based on thermal modeling. As illustrated, audio circuit 200 includes input(s) 201, output(s) 202, audio processor 203, and audio codec 204. Components 201-204 may be operably coupled to one another via Inter-IC Sound (I²S) bus 205 or other suitable bus. Also, in some devices, audio circuit 200 may be coupled to timing circuit 206, processing cores 207A-N, memory 208, and/or input/output (I/O) interface(s) 210 via bus 209. In some cases, components 206-210 may be a part of another device (e.g., a computer, etc.) that is hosting audio circuit 200.

It should be noted that different bus standards may be used to facilitate communication between different ones of components 201-204 and/or between audio circuit 200 and components 206-210. Moreover, in some cases, one or more of components may be directly coupled to each other or embedded within each other (e.g., audio processor 203 may include audio codec 204). As such, it should be understood the particular configurations of audio circuit 200 and other components shown in FIG. 2 are provided for illustration purposes only, and that other configurations are possible.

In operation, audio processor 203 may act either independently or under command of processor core(s) 207A-N to control one or more of components 201-204 (e.g., via I²S 205) in order to implement certain systems and methods for audio power limiting based on thermal modeling. Audio codec 204 may implement one or more algorithms that compress and/or decompress audio data according to a given audio file format or streaming media audio format.

In some embodiments, input(s) 201 and/or output(s) 202 may include, for example, ADCs, DACs, Phased Locked Loop (PLLs), oscillators, filters, amplifiers, etc. Particularly, input(s) 201 may include one or more analog or digital input circuits configured to receive and/or preprocess, analog or digital audio signals (e.g., from a microphone, a line-in connection, an optical source, an S/PDIF line, etc.). Conversely, output(s) 202 may include one or more analog or digital output circuits configured to provide or output analog or digital audio signals to other devices (e.g., to a loudspeaker, headphone, via a line-out connection, an optical line, an S/PDIF line, etc.).

Processor core(s) 207A-N may be any general-purpose or embedded processor(s) implementing any of a variety of Instruction Set Architectures (ISAs), such as the x86, RISC®, PowerPC®, ARMO, etc. In multi-processor systems, each of processor core(s) 210A-N may commonly, but not necessarily, implement the same ISA.

Memory 208 may include for example, a RAM, a SRAM, MRAM, a NVRAM, such as “FLASH” memory, and/or a DRAM, such as SDRAM, a DDR RAM, an EPROM, an EEPROM, etc.

Bus 209 may be used to couple master and slave components together, for example, to share data or perform other data processing operations. In various embodiments, bus 209 may implement any suitable bus architecture, including, for instance, Advanced Microcontroller Bus Architecture® (AMBA®), CoreConnect™ Bus Architecture™ (CCBA™), etc. Additionally or alternatively, bus 209 may be absent and timing circuit 206 or memory 208, for example, may be integrated into processor core(s) 207A-N.

In various embodiments, modules or blocks shown in FIG. 2 may represent processing circuitry, logic functions, and/or data structures. Although these modules are shown as distinct blocks, in other embodiments at least some of the operations performed by these modules may be combined in to fewer blocks. Conversely, any given one of the modules of FIG. 2 may be implemented such that its operations are divided among two or more logical blocks. Although shown with a particular configuration, in other embodiments these various modules or blocks may be rearranged according to other suitable embodiments.

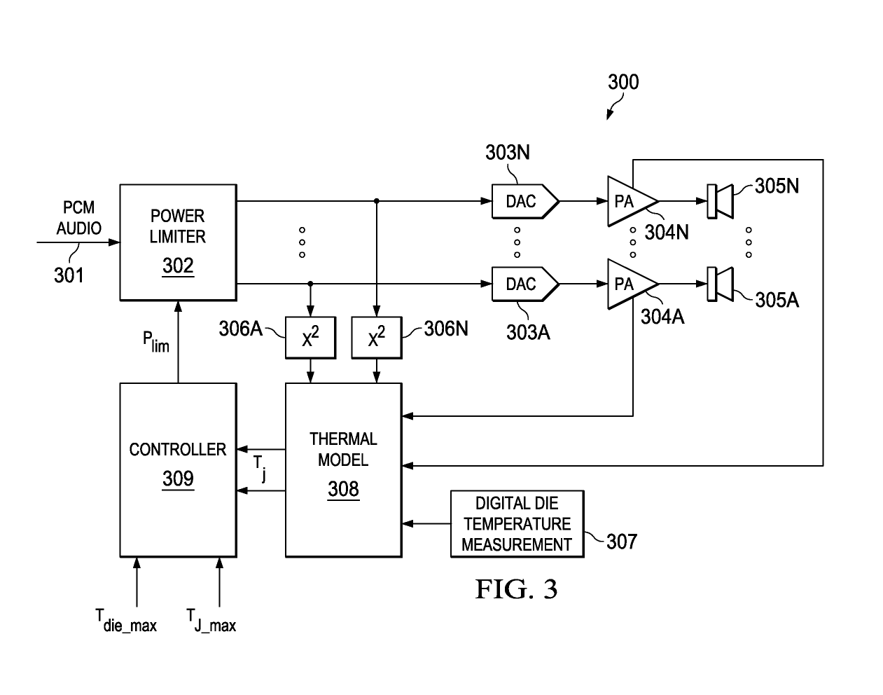

FIG. 3 is a block diagram of an example of a circuit for audio power limiting based on thermal modeling according to some embodiments. Particularly, circuit 300 includes audio signal source 301, in this non-limiting embodiment illustrated as a Pulse Code Modulated (PCM) audio signal, fed into power limiter 302. Power limiter 302 is coupled to a plurality of audio channels A-N, each of which include a respective Digital-to-Analog Converter (DAC) 303A-N coupled to a power amplifier 304A-N. Each channel may be coupled to a respective one of loudspeakers 305A-N. In some implementations, only one power stage may be used. In other implementations, two channels (e.g., stereo) may be used. More generally, any number of channels may be used (e.g., surround channels).

Each of power amplifiers 304A-N is coupled to thermal model 308, so that thermal model 308 is configured to receive temperature measurements from one or more MOSFETS within power amplifiers 304A-N. Thermal model 308 also receives a power estimation (X²) 306A-N from each channel, and a temperature measurement 307 from the digital die. Controller 309 is coupled to thermal model 308 and receives one or more additional parameters, including threshold temperatures T_{die}_{_}ₘₐₓ and T_{J}_{_}ₘₐₓ, for example, from a user.

In operation, controller 309 receives temperature estimations Tⱼ provided by thermal model 308 and provides instructions Pᵢᵢₘ to reduce or control the power of signal 301, in order to avoid allowing the MOSFESTs within power amplifiers 304A-N to reach their maximum threshold temperatures. These, and other operations, are described in more detail below.

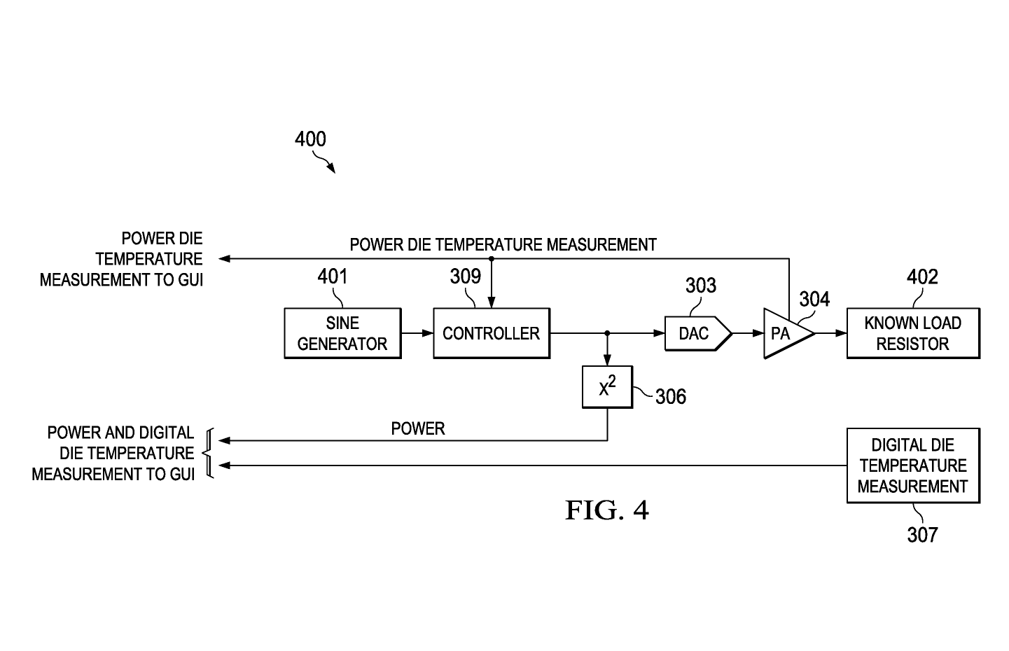

FIG. 4 is a block diagram of the circuit being used in a parameter estimation mode according to some embodiments. In various implementations, circuit 300 of FIG. 3 may be used in configuration 400 of FIG. 4 in order to measure a number of model parameters including, but not limited to, a thermal time constant for a MOSFET and a thermal time constant for a digital circuit, a thermal resistance for the MOSFET and a thermal resistance for the digital circuit, and a thermal resistance between the MOSFET and the ambient, among others.

In parameter estimation configuration 400, signal generator 401 provides a known audio input (in this case, a sine wave) to controller 309, which in turn is coupled to DAC 303. Meanwhile, loudspeakers 305A-N are replaced with resistor(s) 402 having a known load. In various implementations, a power die temperature measurement from power amplifier 304 is provided to controller 309 as well as to a user via a graphical user interface (GUI) or the like. Similarly, a power measurement 306, and a digital die temperature measurement are also provided to controller 309 and/or to a GUI.

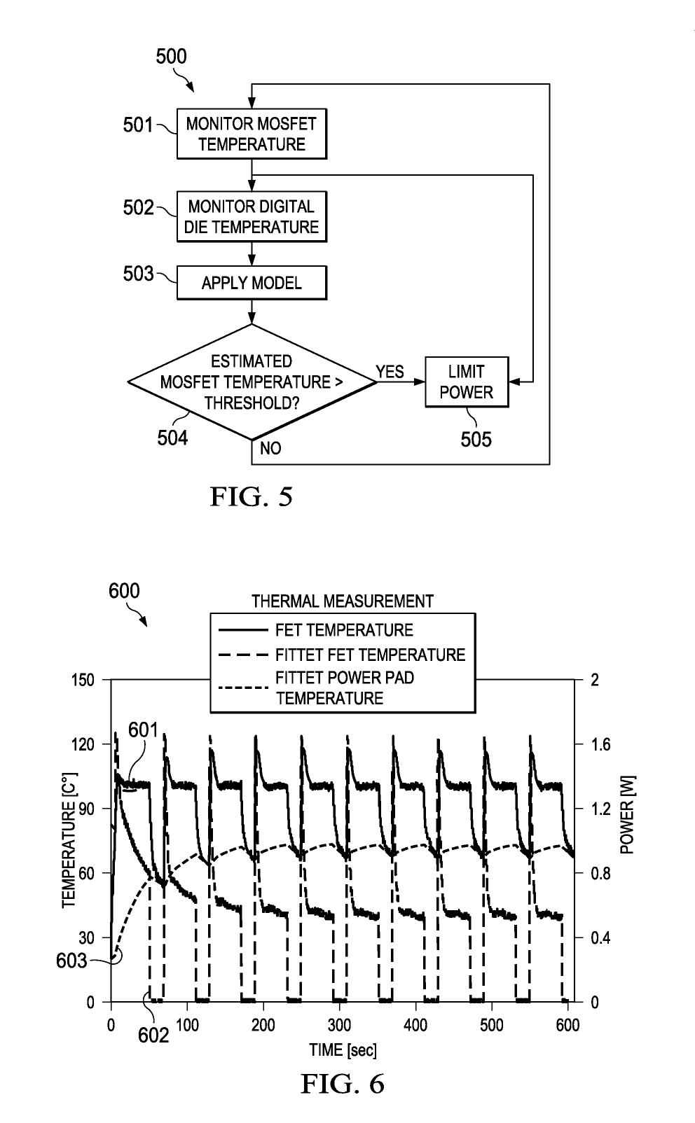

FIG. 5 is a flowchart of an example of a method for audio power limiting based on thermal modeling. In various embodiments, method 500 may be performed, at least in part, by thermal model 308, controller 309, and power limiter 302. Specifically, at block 501 method 500 includes monitoring the current temperature of a MOSFET within power amplifier 304. At block 502 method 500 monitors a current temperature of a digital die. For example, a temperature sensor on the digital die may be in the form of a temperature output of a bandgap regulator. Then, at block 603, a model may be applied.

In some embodiments, the thermal model may include a 2^{nd} order state space model or the like. For instance, in a non-limiting embodiment, such a model may be given by:

$${T}_{v} ( t ) = {P}_{i} ( {R}_{v} + {R}_{m} ) - ( {T}_{v} ( t ) - {T}_{m} ( t ) ) {e}^{- \frac{t}{{R}_{v} {C}_{v}}} - ( {T}_{m} ( t ) - {T}_{a} ( t ) ) {e}^{- \frac{t}{{R}_{m} {C}_{m}}}$$

where: Tᵥ(t) is the voice coil temperature, Tₐ(t) is the ambient temperature, Tₘ(t) is the magnet temperature, Pᵢ is the power dissipated in the voice coil, Rᵥ is the thermal resistance from the voice coil to the magnet, Rₘ is the thermal resistance from the magnet to the ambient, Cᵥ is the thermal capacitance of the voice coil, and Cₘ is the thermal capacitance of the magnet.

At block 504, method 500 determines whether the estimated MOSFET temperature reaches the threshold. If not, control returns to block 501. For example, in some embodiments, the monitoring operations of blocks 501 and 502 may be performed continuously or periodically. If the estimated MOSFET temperature reaches the threshold, however, block 505 may limit the amplitude of input signal 301 according to latest monitored MOSFET and digital die temperatures so that the current MOSFET temperature stays below the threshold, effectively creating a thermal fold back mechanism that allows the audio signal to continue to be amplified by power amplifier 304 and reproduced by speakers 305 without being stopped due to an over-temperature condition.

FIG. 6 is a graph of various temperature and power measurements performed by the circuit according to some embodiments. Curve 603 shows a MOSFET's temperature in the power pad, as it rises and stabilizes in a controlled manner when power 602 is limited using method 500, and curve 601 shows the heatsink temperature, with a longer thermal time constant.

It should be understood that the various operations described herein, particularly in connection with FIG. 5, may be implemented by processing circuitry or other hardware components. The order in which each operation of a given method is performed may be changed, and various elements of the systems illustrated herein may be added, reordered, combined, omitted, modified, etc. It is intended that this disclosure embrace all such modifications and changes and, accordingly, the above description should be regarded in an illustrative rather than a restrictive sense.

A person of ordinary skill in the art will appreciate that the various circuits depicted above are merely illustrative and is not intended to limit the scope of the disclosure described herein. In particular, a device or system configured to perform audio power limiting based on thermal modeling may include any combination of electronic components that can perform the indicated operations. In addition, the operations performed by the illustrated components may, in some embodiments, be performed by fewer components or distributed across additional components. Similarly, in other embodiments, the operations of some of the illustrated components may not be provided and/or other additional operations may be available. Accordingly, systems and methods described herein may be implemented or executed with other circuit configurations.

It will be understood that various operations discussed herein may be executed simultaneously and/or sequentially. It will be further understood that each operation may be performed in any order and may be performed once or repetitiously.

Many modifications and other embodiments of the invention(s) will come to mind to one skilled in the art to which the invention(s) pertain having the benefit of the teachings presented in the foregoing descriptions, and the associated drawings. Therefore, it is to be understood that the invention(s) are not to be limited to the specific embodiments disclosed. Although specific terms are employed herein, they are used in a generic and descriptive sense only and not for purposes of limitation.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. A method, comprising:
monitoring a first temperature of a power die within an audio system;
monitoring a second temperature of a digital die within the audio system; and
using the first and second temperatures to limit an amplitude of an audio signal provided to a Metal-Oxide-Semiconductor Field-Effect Transistor (MOSFET) of an amplifier within the audio system to keep an operating temperature of the MOSFET under a thermal protection threshold without stopping the audio signal from being output by the audio system.

2. The method of claim 1, wherein using the first and second temperatures includes using a thermal model.

3. The method of claim 2, wherein the thermal model includes a 2^{nd} order state space model.

4. The method of claim 2, wherein the model uses a plurality of parameters including a maximum temperature for the power die and a maximum temperature for the digital die.

5. The method of claim 2, wherein the model uses a plurality of parameters including a thermal time constant for the MOSFET and a thermal time constant for the digital die.

6. The method of claim 2, wherein the model uses a plurality of parameters including a thermal resistance for the MOSFET and a thermal resistance for the digital die.

7. The method of claim 2, wherein the model uses a plurality of parameters including a thermal resistance between the MOSFET and an ambient where the MOSFET is located.

8. The method of claim 1, wherein the monitoring operations are performed continuously or periodically, and wherein the amplitude of the audio signal is limited according to latest monitored first and second temperatures.

9. An audio system, comprising:
an analog circuit comprising a power amplifier and a Metal-Oxide-Semiconductor Field-Effect Transistor (MOSFET) within the power amplifier; and
a digital circuit coupled to the analog circuit, the digital circuit comprising:
an audio signal source;
a digital-to-analog converter (DAC) coupled to the audio signal source and to the power amplifier; and
a controller coupled to the audio signal source, the controller configured to:
periodically receive a first temperature of the digital circuit;
periodically receive a second temperature of the MOSFET, wherein the first and second temperatures change over time; and
use the first and second temperatures to dynamically limit an amplitude of an audio signal provided by the audio signal source to the DAC in order to keep an operating temperature of the MOSFET under a thermal protection threshold without stopping the audio signal from being output by the analog circuit.

10. The audio system of claim 9, wherein the controller comprises a thermal model estimator configured to implement a thermal model, and wherein the thermal model uses plurality of parameters including a maximum temperature for the MOSFET and a maximum temperature for the digital circuit, a thermal time constant for the MOSFET and a thermal time constant for the digital circuit, a thermal resistance for the MOSFET and a thermal resistance for the digital circuit, and a thermal resistance between the MOSFET and the ambient.

11. The audio system of claim 10, wherein the controller is further configured to estimate the plurality of parameters, at least in part, by replacing the audio signal with a test signal prior to performing the limiting operation.

12. The audio system of claim 10, wherein the controller comprises a power integrator coupled to the thermal model estimator.

13. The audio system of claim 12, further comprising a power limiter coupled to the power integrator and to the audio signal source.

14. A circuit, comprising:
a controller; and
a memory coupled to the controller, the memory having program instructions stored thereon that, upon execution by the controller, cause the circuit to:
monitor a first temperature of an analog die;
monitor a second temperature of a digital die; and
use the first and second temperatures to limit an amplitude of an audio signal provided to a Metal-Oxide-Semiconductor Field-Effect Transistor (MOSFET) to keep an operating temperature of the MOSFET under a thermal protection threshold without stopping an audio signal from being output by the MOSFET.

15. The circuit of claim 14, wherein using the first and second temperatures includes using a thermal model.

16. The circuit of claim 15, wherein the model uses plurality of parameters including a maximum temperature for the analog die and a maximum temperature for the digital die.

17. The circuit of claim 15, wherein the model uses plurality of parameters including a thermal time constant for the analog die and a thermal time constant for the digital die.

18. The circuit of claim 15, wherein the model uses plurality of parameters including a thermal resistance for the analog die and a thermal resistance for the digital die.

19. The circuit of claim 15, wherein the model uses plurality of parameters including a thermal resistance between the analog die and an ambient where the MOSFET is located.

20. The circuit of claim 14, wherein the monitoring operations are performed continuously or periodically, and wherein the amplitude of the audio signal is limited according to latest monitored first and second temperatures.
